(19) United States
(12) Patent Application Publication
(10) Pub. No.: US 2025/0332834 A1
(43) Pub. Date: Oct. 30, 2025

(54) ULTRASONIC VIBRATION-ASSISTED PRINTING ENHANCEMENT MODULE

(71) Applicants: The Curators of the University of Missouri, Columbia, MO (US); University of Mississippi, University, MS (US)

(72) Inventors: Yi Wang, Columbia, MO (US); Yiwei Han, Columbia, MO (US)

(21) Appl. No.: 19/195,123

(22) Filed: Apr. 30, 2025

Related U.S. Application Data
(60) Provisional application No. 63/640,400, filed on Apr. 30, 2024.

(51) Int. Cl. B41J 2/165; B41J 2/175; H10N 30/20; H10N 30/87

(52) U.S. Cl. CPC B41J 2/16502; B41J 2/175; H10N 30/20; H10N 30/87

(57) ABSTRACT

An ultrasonic vibration-assisted printhead, wherein the printhead comprises a print material reservoir structured and operable to retain a print material, a dispensing nozzle fluidly connected to the print material reservoir and structured and operable to dispense print material received from the print material reservoir; and a piezoelectric ultrasonic vibration printing enhancement module (PEM) operably connected to the dispensing nozzle and structured and operable to generate and propagate ultrasonic vibration to the dispensing nozzle to prevent clogging of the print material within dispensing nozzle during dispensing of the print material.

### CROSS-REFERENCE TO RELATED APPLICATIONS

This application claims the benefit of U.S. Provisional Application No. 63/640,400, filed on Apr. 30, 2024. The disclosure of the above application is incorporated herein by reference in its entirety.

### FIELD

The present disclosure relates generally to an ultrasonic vibration-assisted printhead (VAPH) that can be applied to most nozzle-based printing technologies, such as Electrohydrodynamic (EHD) printing, inkjet printing, direct ink writing, etc., with various inks to improve the printing performance and printing capability thereof.

### BACKGROUND

The statements in this section merely provide background information related to the present disclosure and may not constitute prior art.

Electrohydrodynamic (EHD) printing is a cost-effective, high-resolution printing technology that can produce fine droplets or jets of ink with a size much smaller than the printing nozzle size. In EHD printing, printing materials (such as polymers, conductive nano inks, quantum materials, and ceramic solutions) are subjected to a high electric field to form a Taylor-cone structure. When the electrostatic force exceeds the ink surface tension and viscous force, a fine drop or jet can be generated. EHD printing does not require a dedicated machine or complex post-process. Additionally, EHD can easily accommodate various printing materials (such as polymers, conductive nano inks, quantum materials, ceramic solutions, and melts) for a wide range of applications.

While EHD printing can create features smaller than the nozzle size, it becomes more susceptible to nozzle clogging when employing smaller nozzle sizes. The issue of nozzle clogging poses a critical challenge in EHD printing and other nozzle-based printing due to solvent evaporation, ink drying near or within the nozzle tip, high print material viscosity, and high print material concentrations, which prevents utilizing EHD printing with functional and novel materials for nanoscale fabrication. For example, electrically conductive contents (e.g., particles, nanowires, flakes) are often added to a solution carrier to form functional printing inks. A high concentration of electrically conductive content suspended in the printing inks tends to aggregate or precipitate over extended periods at the nozzle tip, significantly disrupting the printing process and preventing continuous printing. For nano-resolution EHD printing, a high-resolution nozzle with an inner diameter of a few micrometers or less is usually required. The smaller nozzle diameters are more sensitive to the viscosity of the ink, increasing the risk of nozzle clogging. Extensive experiments have demonstrated that an ink viscosity of higher than 90 mPas will easily cause nozzle clogging, which prevents the usage of a range of polymer materials in high-resolution applications. While these adjustments may be acceptable for specific applications, it is still challenging for large-scale pattern printing, and post processes are required to remove those additives to enhance the functional performance.

Ultrasonic vibration has been demonstrated to improve various manufacturing methods, such as ultrasonic vibration-assisted milling, ultrasonic vibration-assisted turning, ultrasonic vibration-assisted welding, etc., for decades. Employing high-frequency vibration in manufacturing can dramatically reduce the friction force. The superimposed ultrasonic will generate a stick-slip motion between two sliding interfaces, which can reduce the friction force. Applying ultrasonic vibration on fluid extrusion has been proven to improve the rheology (viscosity and elastic strain) and flow behavior, thus improving the extrusion process. Ultrasonic vibration was recently applied to extrusion-based 3D printing technology such as fused deposition modeling (FDM). It has been found that ultrasonic vibration can improve interlayer adhesion due to decreased melt viscosity and physically modified interface wettability. Known experimentation has employed an ultrasonic actuator against the syringe nozzle to print extremely viscous materials. The results of such experimentation have shown that the superimposed ultrasonic vibration is able to effectively reduce wall friction and flow stresses on the nozzle, enabling a lower printing pressure requirement with precise flow control. This promising method is able to print high-viscosity materials with a smaller nozzle and increase the flow velocity of the printing materials. However, the reported ultrasonic vibration-assisted printing methods were enabled by externally attaching an ultrasonic actuator to the nozzle, limiting the ability to fine-tune the vibration characteristics for better printing performance. There exists a need in the art for an apparatus that integrates ultrasonic vibration with EHD printing.

### SUMMARY

The following objects, features, advantages, aspects, and/or embodiments are not exhaustive and do not limit the overall disclosure. No single embodiment need provide each and every object, feature, or advantage. Any of the objects, features, advantages, aspects, and/or embodiments disclosed herein can be integrated with one another, either in full or in part.

In various embodiments the present disclosure provides an ultrasonic vibration-assisted printhead, wherein the printhead comprises a print material reservoir structured and operable to retain a print material, a dispensing nozzle fluidly connected to the print material reservoir and structured and operable to dispense print material received from the print material reservoir, and a piezoelectric ultrasonic vibration printing enhancement module (PEM) operably connected to the dispensing nozzle and structured and operable to generate and propagate ultrasonic vibration to the dispensing nozzle to prevent clogging of the print material within dispensing nozzle during dispensing of the print material.

In various other embodiments the present disclosure provides a piezoelectric ultrasonic vibration printing enhancement module (PEM) for use in a printhead, wherein the module comprises a PEM head chassis, and a piezoelectric head and transducer assembly. In various instances the piezoelectric head and transducer assembly comprises a PEM head retained within the PEM head chassis and structured and operable to generate the ultrasonic vibration, and a transducer mechanically connected to the PEM head.

In yet other embodiments the present disclosure provides a piezoelectric head and transducer assembly for use in a printhead, wherein the piezoelectric head and transducer assembly comprises a piezoelectric ultrasonic vibration printing enhancement module (PEM) head structured and operable to generate the ultrasonic vibration, and a transducer mechanically connected to the PEM head. In various instances the PEM comprises a plurality of electrodes, and a plurality of piezoelectric ceramic disks disposed between the plurality of electrodes that are structured and operable to generate the ultrasonic vibration.

These and/or other objects, features, advantages, aspects, and/or embodiments will become apparent to those skilled in the art after reviewing the following brief and detailed descriptions of the drawings. The present disclosure encompasses (a) combinations of disclosed aspects and/or embodiments and/or (b) reasonable modifications not shown or described.

### BRIEF DESCRIPTION OF THE DRAWINGS

The drawings described herein are for illustration purposes only and are not intended to limit the scope of the present teachings in any way.

FIG. 1 is a block diagram exemplary illustrating an ultrasonic vibration-assisted printhead (VAPH) including a piezoelectric ultrasonic vibration printing enhancement module (PEM), in accordance with various embodiments of the present disclosure.

FIG. 2A is an exemplary illustration of the PEM shown in FIG. 1, in accordance with various embodiments of the present disclosure.

FIG. 2B is an exemplary exploded view of the PEM shown in FIGS. 1 and 2A, in accordance with various embodiments of the present disclosure.

FIG. 2C is an exemplary exploded view of a piezoelectric head and transducer assembly of the PEM shown in FIGS. 1, 2A and 2B, in accordance with various embodiments of the present disclosure.

FIG. 3 is an exemplary illustration of a longitudinal transducer of the piezoelectric head and transducer assembly of the PEM shown in FIGS. 1, 2A, 2B and 2C, in accordance with various embodiments of the present disclosure.

FIG. 4 is an exemplary illustration of a longitudinal-torsional transducer of the piezoelectric head and transducer assembly of the PEM shown in FIGS. 1, 2A, 2B and 2C, in accordance with various embodiments of the present disclosure.

FIG. 5 is an exemplary illustration of the VAPH including the PEM shown in FIGS. 1 through 4, in accordance with various embodiments of the present disclosure.

FIG. 6 is an exemplary illustration of the VAPH including the PEM shown in FIGS. 1 through 4 further comprising a print material mixing chamber, in accordance with various embodiments of the present disclosure.

FIGS. 7A and 7B exemplarily illustrate optical images of printed filaments utilizing a VAPH comprising the PEM shown in FIGS. 1 through 6 with different vibration frequencies from 35 kHz to 80 KHz, and the relationship between the applied amplitude and filament diameter, in accordance with various embodiments of the present disclosure.

FIGS. 8A and 8B exemplarily illustrate optical images of printed filaments utilizing a VAPH comprising the PEM shown in FIGS. 1 through 6 with different amplitude voltages from 35V to 105V, and the relationship between the applied amplitude and filament diameter, in accordance with various embodiments of the present disclosure.

FIGS. 9A and 9B exemplarily illustrate optical images of printed filaments utilizing a VAPH comprising the PEM shown in FIGS. 1 through 6 with different printing voltage from 0.7 kV to 1.5 kV, and the relationship between the applied voltage and filament diameter, in accordance with various embodiments of the present disclosure.

It should be understood that any or all of the features, functions and and/or method steps illustrated in each respective figure can be readily and easily combined with any or all of the features, functions and/or method step illustrated in one or more of the other figures to describe, generate and exemplarily illustrate various embodiments of the present invention that are described and/or claimed herein, and such embodiments would be readily and easily understood and envisioned by one skilled in the art without the need for exemplary illustrations of such embodiments whose features, functions and/or method steps are clearly described and illustrated in the combination of the various figures.

Corresponding reference numerals indicate corresponding parts throughout the several views of drawings.

### DETAILED DESCRIPTION

The present disclosure is not to be limited to that described herein. Mechanical, electrical, chemical, procedural, and/or other changes can be made without departing from the spirit and scope of the present disclosure. No features shown or described are essential to permit the basic operation of the present disclosure unless otherwise indicated.

The following description is merely exemplary in nature and is in no way intended to limit the present teachings, application, or uses. Throughout this specification, like reference numerals will be used to refer to like elements. Additionally, the embodiments disclosed below are not intended to be exhaustive or to limit the invention to the precise forms disclosed in the following detailed description. Rather, the embodiments are chosen and described so that others skilled in the art can utilize their teachings. As well, it should be understood that the drawings are intended to illustrate and plainly disclose presently envisioned embodiments to one of skill in the art, but are not intended to be manufacturing level drawings or renditions of final products and may include simplified conceptual views to facilitate understanding or explanation. As well, the relative size and arrangement of the components may differ from that shown and still operate within the spirit of the invention.

As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to practice the disclosure and are not intended to limit the scope of the appended claims.

Unless otherwise defined, all technical and scientific terms used herein have the same meaning as commonly understood by one of ordinary skill in the art to which this disclosure belongs. The terminology used herein is for the purpose of describing particular example embodiments only and is not intended to be limiting. As used herein, the singular forms “a”, “an”, and “the” may be intended to include the plural forms as well, unless the context clearly indicates otherwise. The terms “comprises”, “comprising”, “including”, and “having” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps can be employed.

When an element, object, device, apparatus, component, region or section, etc., is referred to as being “on”, “engaged to or with”, “connected to or with”, or “coupled to or with” another element, object, device, apparatus, component, region or section, etc., it can be directly on, engaged, connected or coupled to or with the other element, object, device, apparatus, component, region or section, etc., or intervening elements, objects, devices, apparatuses, components, regions or sections, etc., can be present. In contrast, when an element, object, device, apparatus, component, region or section, etc., is referred to as being “directly on”, “directly engaged to”, “directly connected to”, or “directly coupled to” another element, object, device, apparatus, component, region or section, etc., there may be no intervening elements, objects, devices, apparatuses, components, regions or sections, etc., present. Other words used to describe the relationship between elements, objects, devices, apparatuses, components, regions or sections, etc., should be interpreted in a like fashion (e.g., “between” versus “directly between”, “adjacent” versus “directly adjacent”, etc.).

As used herein the phrase “operably connected to” will be understood to mean two are more elements, objects, devices, apparatuses, components, etc., that are directly or indirectly connected to each other in an operational and/or cooperative manner such that operation or function of at least one of the elements, objects, devices, apparatuses, components, etc., imparts or causes operation or function of at least one other of the elements, objects, devices, apparatuses, components, etc. Such imparting or causing of operation or function can be unilateral or bilateral.

As used herein, the term “and/or” includes any and all combinations of one or more of the associated listed items. For example, A and/or B includes A alone, or B alone, or both A and B.

Although the terms first, second, third, etc. can be used herein to describe various elements, objects, devices, apparatuses, components, regions or sections, etc., these elements, objects, devices, apparatuses, components, regions or sections, etc., should not be limited by these terms. These terms may be used only to distinguish one element, object, device, apparatus, component, region or section, etc., from another element, object, device, apparatus, component, region or section, etc., and do not necessarily imply a sequence or order unless clearly indicated by the context.

Moreover, it will be understood that various directions such as “upper”, “lower”, “bottom”, “top”, “left”, “right”, “first”, “second” and so forth are made only with respect to explanation in conjunction with the drawings, and that components may be oriented differently, for instance, during transportation and manufacturing as well as operation. Because many varying and different embodiments may be made within the scope of the concept(s) taught herein, and because many modifications may be made in the embodiments described herein, it is to be understood that the details herein are to be interpreted as illustrative and non-limiting.

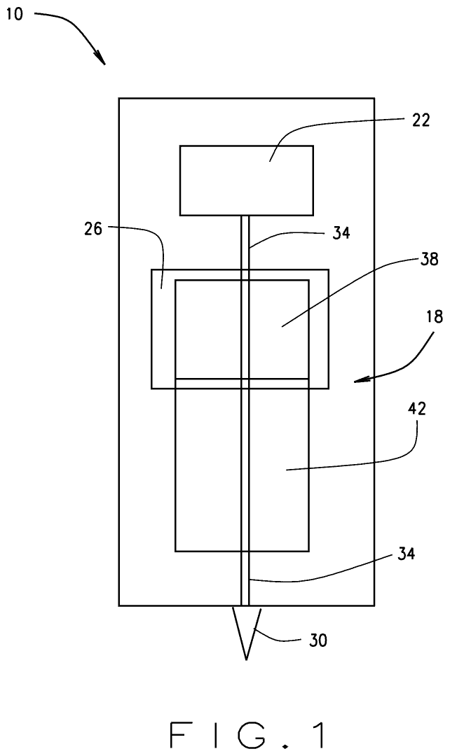

Referring to FIG. 1, generally, in various embodiments the present disclosure provides an ultrasonic vibration-assisted printhead (VAPH) 10 comprising a piezoelectric ultrasonic vibration printing enhancement module (PEM) 18 integrated therein. The PEM 18 is structured and operatable to provide a nozzle-clogging-free printing of materials with high viscosity and high solvent evaporation rate. The VAPH 10 generally comprises the PEM 18, a print material reservoir 22, a PEM head chassis 26, a dispensing nozzle 30 and a supply conduit 34 fluidly connecting the print material reservoir 22 with the dispensing nozzle 30. The print material reservoir 22 is structured and operable to have disposed therein and retain a liquid print material such as standard inks, polymers, conductive nano inks, quantum materials, ceramic solutions, melts, etc. The PEM head chassis 26 is structured and operable to retain and secure a PEM head 38 of the PEM 18, described in detail below. The dispensing nozzle 30 is structured and operable to dispense, direct and control the volume of the print material onto a substrate such as paper, glass, wafer, polydimethylsiloxane (PDMS), polyester (PET) and polymide. The supply conduit 34 is structured and operable to provide a conduit for the print material to flow from the print material reservoir 22 to the dispensing nozzle 30.

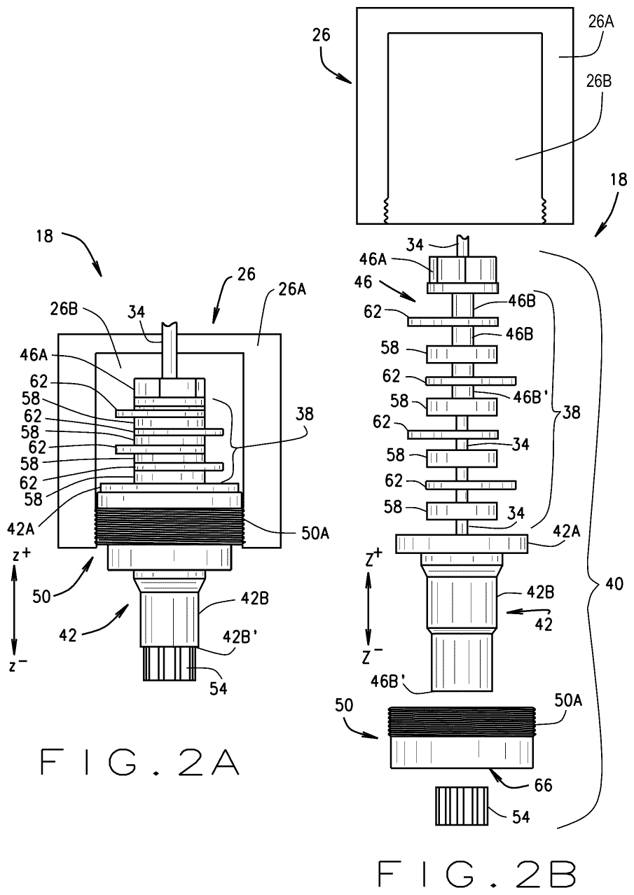

Referring now to FIGS. 2A, 2B and 2C, the PEM 18 comprises the PEM head chassis 26 and a piezoelectric head and transducer assembly 40 that is mounted to the PEM head chassis 26. The piezoelectric head and transducer assembly 40 comprises the PEM head 38, a transducer 42 (e.g., and ultrasonic transducer), a back mass nut 46, an assembly mounting nut 50, and an assembly and nozzle connector 54 (e.g., a Luer connector) that has a threaded center aperture (not shown). The assembly mounting nut 50 has threads formed in and around at least a portion of an outer surface of the assembly mounting nut 50 that is referred to herein as the threaded portion 50A of the assembly mounting nut 50. The PEM head 38 comprises a stack of a plurality piezoelectric ceramic disks 58 (e.g., 2, 3, 4, 5, 6 or more piezoelectric ceramic disks 58) disposed between a plurality of electrodes 62 (e.g., 2, 3, 4, 5, 6 or more electrodes 62). As is known in the art, when a sinusoidal voltage is applied across piezoelectric ceramic disks 58, via the electrodes 62, the piezoelectric ceramic disks 58 will vibrate, more particularly the piezoelectric ceramic disks 58 will ultrasonically vibrate at the frequency based on the frequency of the voltage signal. The transducer 42 is mechanically connected to the PEM head 38 (i.e., the stack of piezoelectric ceramic disks 58 and electrodes 62) via the back mass nut 46, the mounting nut 50 and the assembly and nozzle connector 54, and is operatively connected to the dispensing nozzle 30 via the assembly and nozzle connector 54, as described below. Particularly, the transducer 42 comprises a flange 42A and a vibration translation body 42B. Additionally, the transducer 42 has a threaded center bore 64 sized to receive and have a stem 46B of the back mass nut 46 threading therein. The mounting nut 50 has a center orifice 66 that has a diameter that equal to or larger than the widest outer diameter of the transducer translation body 42B, but smaller than the outer diameter of the transducer flange 42A such that the vibration translation body 42B can be inserted into and through the mounting nut center orifice 66.

Furthermore, the back mass nut 46 comprises a head 46A and the stem 46B extending from the head 46A, and each of the piezoelectric ceramic disks 58 and electrodes 62 have a center aperture (not shown) that is sized to receive and have extend therethrough the back mass nut stem 46B. Still further, the back mass nut stem 46B is threaded at a distal end 46B′ and has a center bore (not shown) that is sized to receive and have extend therethrough the supply conduit 34. To assemble the piezoelectric head and transducer assembly 40, the back mass nut stem 46 is disposed through the center apertures of piezoelectric ceramic disks 58 and the electrodes 62 and threaded into the threaded center bore 64 of the transducer 42 such that the PEM head 38 is abutted against a front face of the back mass nut head 46A, thereby securely mechanically connecting the PEM head 38 with the transducer 42 on the back mass nut 46. Thereafter, the transducer vibration translation body 42B is inserted through the center orifice 66 of the assembly mounting nut 50 and a back face of the assembly mounting nut 50 is abutted against a front face of the transducer flange 42A. Subsequently, the assembly and nozzle connector 54 is threadingly engaged with the assembly mounting nut 50, thereby providing the piezoelectric head and transducer assembly 40. Particularly, the PEM head 38 is directly connected to a back face of the transducer flange 42A when the piezoelectric head and transducer assembly 40 is assembled.

The PEM head chassis 26 comprises an outer shell 26A that defines and surrounds a PEM head cavity 26B. The PEM head cavity 26B is sized and shaped to receive and have disposed therein the PEM head 38. A distal end of the walls of the PEM head cavity 26A has threads formed therein to threadingly receive the threaded portion 50A of assembly mounting nut 50. Hence, once the piezoelectric head and transducer assembly 40 is assembled as described above, the assembled piezoelectric head and transducer assembly 40 can be threadingly connected to the PEM head chassis 26. Consequently, the PEM head 38 is disposed within the PEM head cavity 26B and surrounded by outer shell 26A, such that the PEM head (i.e., the piezoelectric discs 58 and electrodes 62 are electrically isolated and insulated from the ambient environment surrounding the PEM head chassis outer shell 26A.

In operation, voltage is supplied from an ultrasonic voltage driver to the electrodes 62, thereby applying a voltage across the piezoelectric disks 58 causing the piezoelectric disks 58 to vibrate, and more particularly causing the PEM head 38 (i.e., the stacked electrodes 62 and piezoelectric disks 58) to vibrate. Due to the mechanical connection between the transducer flange 42A and the PEM head 38 the vibration of the PEM head 38 is translated or propagated along the longitudinal length of the transducer vibration translation body 42B and transferred or transmitted to the dispensing nozzle 30 through the assembly and nozzle connector 54 causing the dispensing nozzle 30 to vibrate during dispensing of the print material therefrom. The voltage supplied to the electrodes 62 can be controlled and adjusted, via control of the ultrasonic voltage driver, to control and adjust the vibration of the transducer vibration translation body 42B as desired to superimpose the vibration on the dispensing nozzle 30 during dispensing of the print material. For example, in various embodiments, the voltage supplied to the electrodes 62 can be controlled and adjusted, via control of the ultrasonic voltage driver, to control and adjust the vibration of the transducer vibration translation body 42B until the transducer vibration translation body 42B vibrates at a resonant frequency of the transducer vibration translation body 42B (i.e., the natural frequency at which the transducer vibration translation body 42B vibrates most strongly).

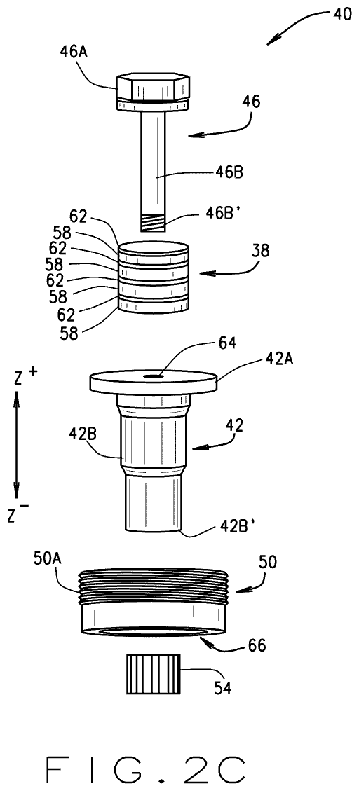

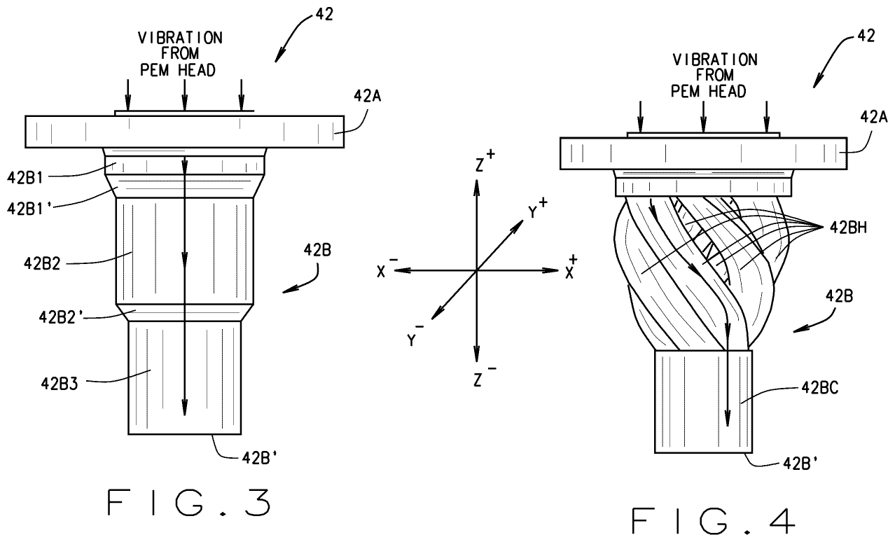

Referring now to FIGS. 3 and 4, the transducer 42 can be fabricated to have any desired size, shape and/or geometry designed to translate or propagate the vibration therethrough from the flange 42A to the distal end 42B′ with a desired direction and amplitude.

For example, as exemplarily illustrated in FIG. 3, in various embodiments, the transducer 42 can have a longitudinal vibration translation body 42B that comprises a plurality of cylindrical sections 42B1, 42B2, etc., wherein each consecutive cylindrical section 42B1, 42B2, etc. from the transducer flange 42A to the vibration translation body distal end 42B′ has a smaller outside diameter than the preceding cylindrical section 42B1, 42B2, etc. For example, as exemplarily illustrated in FIG. 3, in various instances the vibration translation body 42B can have 3 consecutive sections 42B1, 42B2 and 42B3, wherein the outside diameter of section 42B3 is smaller than the outside diameter of section 42B2, and the outside diameter of section 42B2 is smaller than the outside diameter of section 42B1. In such embodiments, the longitudinal vibration translation body 42B is structured and designed to bidirectionally longitudinally translate or propagate the vibration between the PEM head 38 and the transducer distal end 42B′ along the length of the vibration translation body 42B in a Z+ and Z-directions that are parallel to a longitudinal axis of the transducer vibration translation body 42B. More particularly, the vibration from the PEM head 38 is longitudinally translated or propagated through and along length of the cylindrical sections 42B1, 42B2 and 42B3 of transducer vibration translation body 42B in generally a linear path or straight line in the Z-direction between the transducer flange 42A and the transducer distal end 42B′. In various embodiments the vibration translation body 42B can further comprise a plurality of tapered sections 42B1′, 42B2′, etc., wherein each tapered sections 42B1′, 42B2′, etc. are integrally formed between two consecutive cylindrical sections 42B1, 42B2, 42B3, etc. The tapered sections 42B1′, 42B2′, etc. can amplify the vibration at the vibration translation body distal end 42B′. Additionally, the outside diameter and length of each cylindrical section 42B1, 42B2, 42B3, etc. the resonant frequency of the transducer 42 can be adjusted or modified to ensure a highly efficient vibration occurring at the tip of the dispensing nozzle 30.

Alternatively, as exemplarily illustrated in FIG. 4, in various other embodiments, the transducer 42 can have a longitudinal-torsional vibration translation body 42B comprising a plurality of helically shaped wave guide structures or pillars 42BH that extend from the transducer flange 42A to a transducer vibration translation body termination collar 42BC. In such embodiments, the vibrations generated by the PEM head 38 is helically translated or propagated along the helically shaped wave guide structures 42BH in a longitudinal and torsional vibration path (e.g., a helical path) in the Z, Y and Z-directions. The helical waveguide structures 42BH of the longitudinal-torsional vibration translation body 42B convert longitudinal vibration from the PEM head 38 into longitudinal-torsional hybrid vibration, wherein vibration is bidirectionally translated or propagated along the length of the vibration translation body 42B between the PEM head 38 and the transducer distal end 42B′ longitudinally in a Z+ and Z-directions and torsionally within the X-Y plane, as exemplarily illustrated in FIG. 4. In various instances, to parameterize the waveguide design for hybrid the longitudinal-torsional vibration, a circular helix curve was designed as the propagation path, which can be expressed in cylindrical coordinates, as shown in Equation (1).

$$l ( θ ) = \{ \begin{matrix}x ( θ ) = \frac{d}{2} cos θ \\ y ( θ ) = \frac{d}{2} sin θ , \\ z = \frac{L}{2 π} θ\end{matrix} θϵ [ 0 , π ] \qquad ( 1 )$$

Where d is the diameter of the circular helix waveguide path of the waveguide structures 42BH, 0 is the rotational angle of the helically shaped wave guide structures 42BH, and L is the height of the helically shaped wave guide structures 42BH. The helical path has a constant band curvature and constant torsion, which delivers a stable longitudinal and torsional vibration conversion at the vibration translation body distal end 42B′. Each solid waveguide structure 42BH can be generated with a specified diameter. To achieve a symmetrical and high-efficiency longitudinal-torsional vibration at the vibration translation body distal end 42B′, the helically shaped wave guide structures 42BH are circular patterned along the z-axis. Notably, when the rotational angle θ ranges from 0 to 180 degrees, the circular arrangement of the helically shaped wave guide structures 42BH forms a tapered shape. This configuration increases synchronous vibration, facilitating the generation of a harmonic longitudinal-torsional vibration at the vibration translation body distal end 42B′.

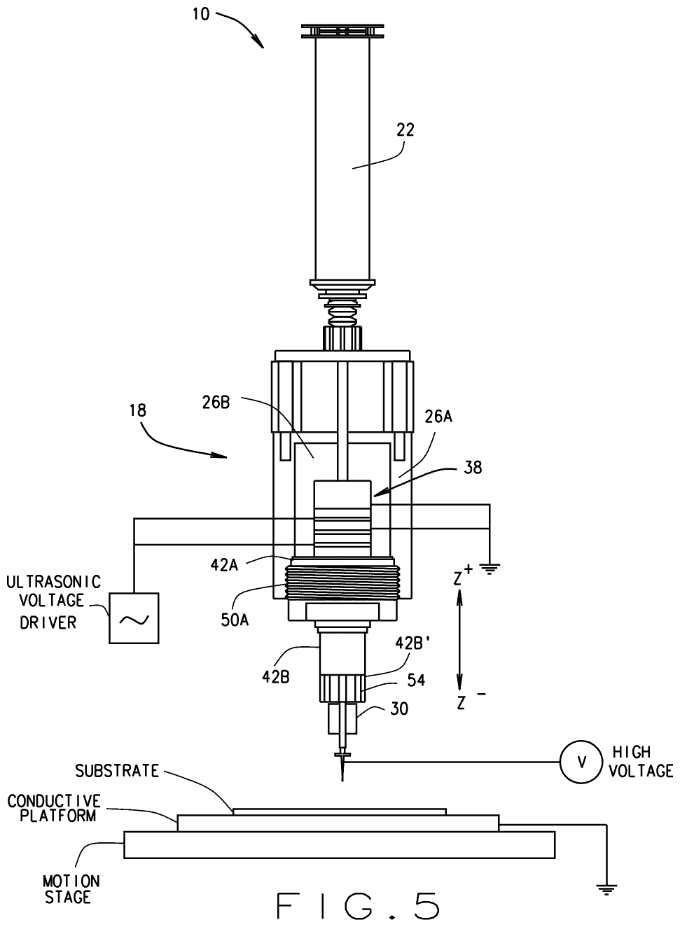

Referring to FIGS. 1 through 6, as exemplarily illustrated in FIG. 5, in various embodiments the ultrasonic vibration-assisted printhead (VAPH) 10 comprising the piezoelectric ultrasonic vibration printing enhancement module (PEM) 18, as described herein, can have the print material reservoir 22 located at or longitudinally adjacent a proximal end of the outer shell 26A such that the print material reservoir is disposed substantially coaxially with a longitudinal center axis of the PEM 18. In such embodiments the print material supply conduit 34 extends from the print material reservoir 22 through the center bore of the back mass nut stem 46B, the transducer center bore 64 and through a center aperture (not shown) of the assembly and nozzle connector 54 to the nozzle 30 as described above.

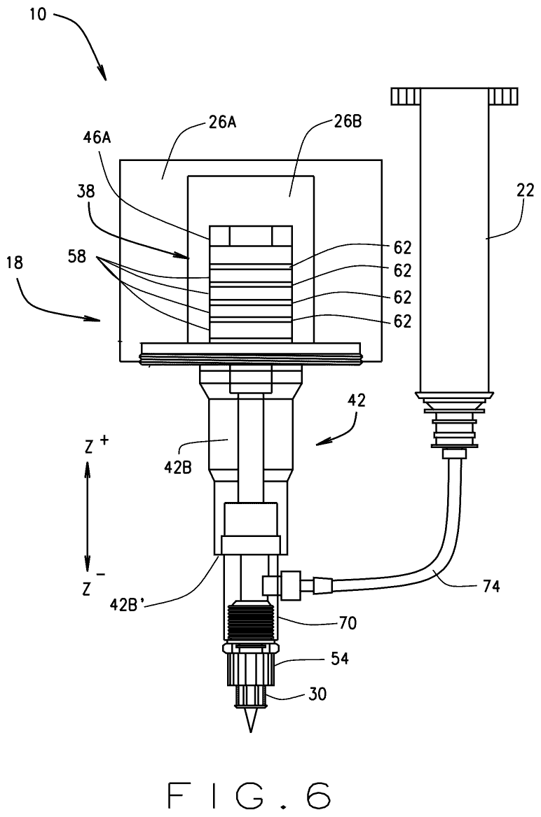

Alternatively, as exemplarily illustrated in FIG. 6, in various embodiments, the VAPH 10 comprising the PEM 18, as described herein, comprises a print material mixing chamber 70 disposed between the distal end 42B′ of the transducer vibration translation body 42B and the assembly and nozzle connector 54. In such embodiments, the print material mixing chamber 70 is mechanically connected to the distal end distal end 42B′ of the transducer vibration translation body 42B such that vibration from the transducer 42 will mix print material disposed within the print material mixing chamber 70 prior to dispensing. More particularly, in such embodiments the print material reservoir 22 is fluidly connected to the print material mixing chamber 70 via a print material supply tube 74 such that print material disposed within the print material reservoir 22 will flow from the print material reservoir 22, through the print material supply tube 74 into the print material mixing chamber 70. In various instances the VAPH 10 can be used to dispense functional printing inks. In such instances, the print material can be a conductive nano ink or any other print material having nanoparticles, nanowires, nanoflakes, etc. dispersed within a liquid ink solution. Accordingly, in such embodiments, during operation of the VAPH 10 the print material having the nanomaterials dispersed therein will flow into the print material mixing chamber 70 where the nanomaterials are thoroughly mixed and/or homogenously dispersed within the ink solution via the vibrations translated from the transducer 42 through the print material mixing chamber 70 to the print nozzle 30. Thoroughly mixing the nanomaterials within the ink solution will prevent or reduce the likelihood of the nanoparticles clogging the nozzle 30.

The PEM 18 as described herein can be implemented and integrated into any printhead of generally any nozzle-based printing technology to render or convert the respective printhead into the VAPH 10, such as electrohydrodynamic (EHD) printing, extrusion printing, electrospray, electrospinning, inkjet printing, direct printing print heads, etc., to improve printing performance and printing capability of such printheads and technologies. By superimposing high frequency and high amplitude vibration, the PEM 18 enables printing of high-viscosity, high solids loading, and volatile materials compared to conventional printing techniques. In addition, the ultrasonic vibration can effectively prevent the nozzle from clogging with a smaller nozzle size.

### Experimentation and Testing

Referring to FIG. 5, for experimentation and testing, a universal piezoelectric ultrasonic vibration printing enhancement module (PEM) 18 was designed and developed to be easily integrated into an EHD printhead or other nozzle-based printhead. A Langevin-type ultrasonic piezoelectric head and transducer assembly 40, consisting of a plurality of pieces of PZT-8 piezoceramic discs sandwiched between the back mass nut 46 and the transducer flange 42A was developed to generate high-power ultrasonic vibration efficiently. The flange 42A of the transducer was designed and optimized to provide stable mechanical support and efficient vibration transfer. When excited by a sinusoidal voltage signal, the piezoceramic stack (i.e., the PEM head 38) transmitted a longitudinal vibration forward to the printing nozzle 30. In order to successfully dispense the inks a silicone supply conduit 34 was disposed within the transducer center bore 64 and connected to the print material reservoir 22 and assembly and nozzle connector 54. The designed piezoelectric head and transducer assembly 40 had a resonance frequency of 55 KHz.

To evaluate the enhanced printing capability, high viscosity, and high evaporation rate, PEO ink was selected. The printing material was prepared by mixing DI water and Poly (ethylene oxide) (PEO) powder with a molecular weight of 1,000,000. The prepared ink contained a PEO weight ratio of 4%. The ultrasonic vibration-assisted EHD printing system consisted of the integrated ultrasonic vibration-assisted printhead (VAPH) 10 described above, a high-precision three-axis stage with repeatability of 50 nm, a voltage supply, a pneumatic dispensing system (including a compressor and a precision regulator), and a high-resolution camera. The piezoelectric ultrasonic vibration printing enhancement module (PEM) 18 was connected to the ultrasonic driver (e.g., a PDU210) to control the vibration frequency and amplitude of the PEM 18, particularly of the piezoelectric head and transducer assembly 40. The power of the vibration amplitude was controlled by the voltage supplied to the electrodes 62 by the ultrasonic driver. Pressure was connected to the print material reservoir 22 to help the print material (e.g., ink) flow to the nozzle 30 before printing. The high-voltage supply with a maximum voltage of 10 kV was connected to the EHD printing nozzle 30 to generate the electrostatic force for the printing. The nozzle 30 was selected to have an orifice of 51 μm for printing. A ground electrode was placed on the motion stage, and a glass substrate was placed on the ground electrode for the EHD printing. The camera with a resolution of 1 μm was used to monitor the printing process.

A PEO solution was loaded into the print material reservoir 22 and a pressure of 0.4 psi was applied to the print material reservoir 22 to bring print material to the top of the nozzle 30. Then, the pressure was removed from the print material reservoir 22. No pressure was applied during the experiment. The vibration frequency and power of the PEM 18, particularly the piezoelectric head and transducer assembly 40, were set to 55 KHz and 75 V, respectively. The EHD printing voltage was selected as 1 kV. To test the effectiveness of the designed PEM 18, three different experiments were performed. At the time of 0 seconds, both printing voltage and vibration were applied for all three experiments to avoid clogging the nozzle. For the first experiment, both printing voltage and vibration were kept after time 0, and for the second and third experiments, only printing voltage or vibration were applied in the system after time 0. A camera was used to record the printing behaviors for all three experiments.

The effectiveness of the integrated ultrasonic VAPH 10 was tested first. At time 0, a fine jet was observed for all three conditions. Initially, a Taylor cone was formed at the nozzle 30 tip, and a fine jet was produced. The cone evolved during the first 35 seconds, and a stable cone shape formed after 35 seconds. This cone shape allowed continuous stable jetting for over 3 minutes in the experiment, demonstrating the long-period printing capability. In the absence of an electric field, the VAPH 10 lacked sufficient force to carry out the ink. As a result, the cone contracted, and no inkjet was observed even after a 10-second. When only voltage is applied, at the beginning (from 0 to 20 seconds), a jet can be formed. However, the shape of the cone continues to change, and an unstable jetting behavior was observed. At the time of 25 seconds, the cone contracted, and only a small amount of materials was carried out from the nozzle 30, which indicated the drying process of the PEO material. When the drying rate or the solution evaporation rate is higher than the material jetting rate, a dried film starts to form at the nozzle 30 tip. The film expands from the edge to the center and eventually cover all areas of the nozzle 30 tip, resulting in nozzle 30 clogging.

Vibration frequency, vibration amplitude, and printing voltage have been identified as key factors in the printing operation of the ultrasonic vibration-assisted printhead (VAPH) 10 comprising the piezoelectric ultrasonic vibration printing enhancement module (PEM) 18 described above. During the testing described above, the ultrasonic vibration (i.e., the vibration of the piezoelectric head and transducer assembly 40) was controlled by the ultrasonic voltage driver operable to provide a vibration frequency between 20 KHz and 100 KHz and an amplitude voltage between 0 V and 105 V. Higher voltage will generate a larger amplitude. Each factor was characterized at a time with the control variable method. The selected ranges for each factor were 35 KHz to 80 KHz for vibration frequency, 35 V to 105 V for vibration amplitude, and 0.7 kV to 1.5 kV for printing voltage. The standoff distance of 700 μm was selected to reduce the disturbance during the printing. The printing speed of 20 mm/s was selected to best match the EHD jetting speed. The printed filaments were observed and measured using a Zeiss Axio Imager MI.

The optimal vibration and printing parameters identified in the characterization process were used for patterning. A grid pattern was meticulously designed in the ACS SPC software and directly transferred to SPiiPlus MMI for direct printing. The printing speed was 20 mm/s to provide the best printing performance. Grid patterns with two different strand-strand gaps (i.e., 20 μm and 100 μm) were used to demonstrate the production capability of the ultrasonic vibration-assisted EHD printing process using the integrated ultrasonic VAPH 10 comprising the PEM 18 of the present disclosure. The printed patterns were measured using an optical microscope.

Moreover, during the material drying process, the cone dynamically changes, thus resulting in an unstable printing starting from the initial stage. This unstable printing process indicated that only applying voltage is not enough for even a short period of printing. All of the results demonstrated that superimposing ultrasonic vibration can effectively prevent the ink from drying and help to provide a stable fine jetting process. The PEM 18 introduces the vibration to the printing system (e.g., the EHP printhead), which reduces the ink shear stress and friction between the ink and nozzle 30 walls, thus increasing the ink flow rate of the nozzle 30. When the ink flow rate is higher than the evaporation rate or material drying rate, continuous jetting can be obtained.

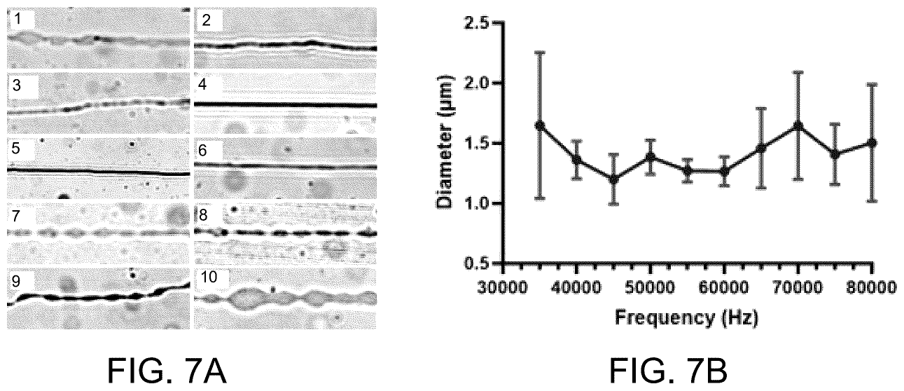

Referring to FIGS. 7A and 7B, as described above, vibration frequency, vibration amplitude, and applied printing voltage are the key factors affecting the printing behavior and results of the VAPH 10 comprising the PEM 18 described above. FIGS. 7A and 7B show the printed filament under different vibration frequencies. There are no obvious changes in the filament diameter, but the quality of the filament varies among different frequencies. VAPH 10 used in this experiment had a resonance frequency of 55 kHz. When the vibration frequency was close to this frequency, more uniform filaments were obtained, as shown in FIGS. 7A-4 through 7A-6). When the vibration frequency deviated from the resonance frequency of the transducer 42, filaments with irregular shapes were observed as illustrated in FIGS. 7A-1 through 7A-3 and 7A-7 through 7A-10). This can be explained as that when the vibration frequency is close to the resonance frequency of the transducer 42, the nozzle 30 tip can reach the maximum amplitude, which can significantly reduce the ink viscosity, thus increasing the ink flow rate and reducing the required force to carry out the ink.

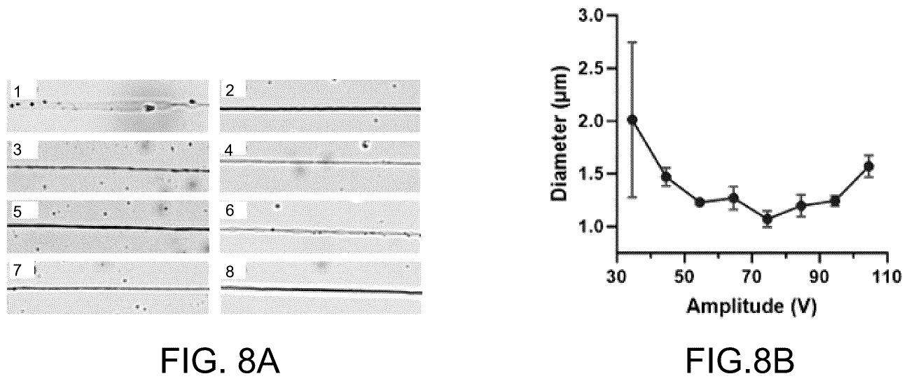

FIGS. 8A and 8B exemplarily illustrate the relation between the vibration amplitude and filament diameter with a vibration frequency of 55 kHz and an applied voltage of 1 kV. When a small amplitude voltage of 25 V was applied, filaments with large variances in diameter were printed, which is shown in FIG. 8A-1. The small vibration amplitude only reduces little ink shear stress; thus, it still requires a larger force to carry out the ink. When the applied printing voltage cannot provide enough force, irregular filaments are printed. When gradually increasing the amplitude power to 75 V, a more uniform filament was observed, and the diameter of the filament decreased (FIGS. 8A-2 through 8A-5)). Moreover, less variation was seen in those filament dimensions, indicating the stable printing process. This can be explained by the fact that increasing the voltage will increase the amplitude, thus further reducing the ink shear stress and the required force for continuous printing. After continuously increasing the voltage, the filament diameter also increased (FIGS. 8A-6 through 8A-8). A higher vibration amplitude dramatically reduced the ink viscosity, and ink was easily dispensed due to the large vibration amplitude.

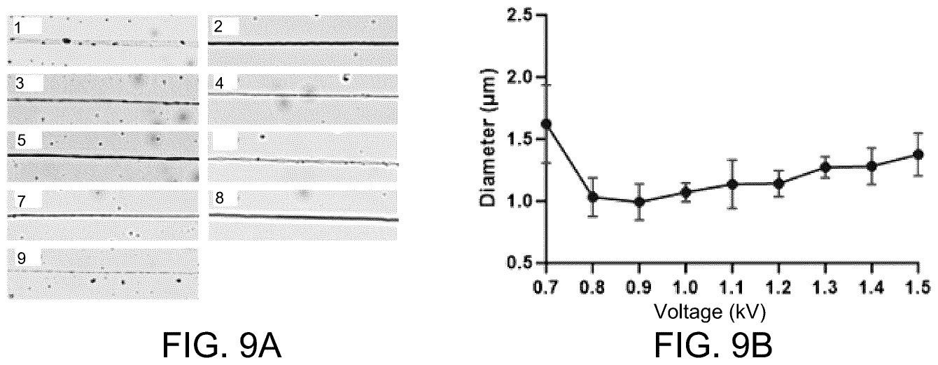

FIGS. 9A and 9B exemplarily illustrate the relationship between the applied printing voltage and filament diameter when applying a constant vibration frequency of 55 kHz and amplitude power of 75 V. When the printing voltage was less than 0.7 kV, no filament was printed on the substrate. After applying a voltage of 0.7 kV, a filament was observed in FIG. 9A-1). However, due to the insufficiency of the voltage, the printed filament exhibited a nonuniform shape and large variation in diameter. When applying a voltage of 0.8 kV, a continuous straight filament was ejected from the Taylor-cone, indicating a stable jetting shown in FIG. 9A-2). Further increasing the voltages, the diameters were increased, as shown in FIGS. 9A-3 through 9A-9). Increasing the voltage increased the electrostatic force; thus, more print material was dispensed. With the same printing speed, a larger diameter was obtained to match the ejected volume of materials.

Optimal process parameters were obtained from these experiments. A filament with the smallest diameter and less variance in diameter is the best for high-resolution patterning. To achieve the best printing result, the vibration frequency, amplitude power voltage, and applied printing voltage were selected as 55 kHz, 75 V, and 1 kV, respectively. With selected process parameters, filaments with a diameter of around 1 m, which is about 1/50 of the nozzle orifice, were printed during the printing process. The results showed that fine grids can be printed even with high printing speed for large-scale patterns. Moreover, the printed grids show excellent transparency. All results demonstrated the excellent stability of the VAPH 10 comprising the PEM 18 described herein for large-scale high-resolution patterning, as well as the potential for fabricating transparent patterns.

The description herein is merely exemplary in nature and, thus, variations that do not depart from the gist of that which is described are intended to be within the scope of the teachings. Moreover, although the foregoing descriptions and the associated drawings describe example embodiments in the context of certain example combinations of elements and/or functions, it should be appreciated that different combinations of elements and/or functions can be provided by alternative embodiments without departing from the scope of the disclosure. Such variations and alternative combinations of elements and/or functions are not to be regarded as a departure from the spirit and scope of the teachings.

What is claimed is:

1. An ultrasonic vibration-assisted printhead, said printhead comprising:
a print material reservoir structured and operable to retain a print material;
a dispensing nozzle fluidly connected to the print material reservoir and structured and operable to dispense print material received from the print material reservoir; and
a piezoelectric ultrasonic vibration printing enhancement module (PEM) operably connected to the dispensing nozzle and structured and operable to generate and propagate ultrasonic vibration to the dispensing nozzle to prevent clogging of the print material within dispensing nozzle during dispensing of the print material.

2. The printhead of claim 1, wherein the PEM comprises:
a PEM head chassis; and
a piezoelectric head and transducer assembly, the piezoelectric head and transducer assembly comprising:
a PEM head retained within the PEM head chassis and structured and operable to generate the ultrasonic vibration; and
a transducer mechanically connected to the PEM head.

3. The printhead of claim 2, wherein the PEM head comprises:
a plurality of electrodes; and
a plurality of piezoelectric ceramic disks disposed between the plurality of electrodes that are structured and operable to generate the ultrasonic vibration.

4. The printhead of claim 3, wherein the transducer comprises:
a flange; and
a vibration translation body extending from the flange that is structured and operable to propagate the ultrasonic vibration between the flange and a distal end of the vibration translation body.

5. The printhead of claim 4, wherein the vibration translation body comprises a longitudinal vibration translation body having a plurality of consecutive cylindrical sections wherein each consecutive cylindrical section from the flange to the distal end has an outer diameter that is smaller than the preceding.

6. The printhead of claim 5, wherein the longitudinal vibration translation body further comprises a plurality of tapered sections, wherein each tapered is integrally formed between two consecutive cylindrical sections.

7. The printhead of claim 4, wherein the vibration translation body comprises a longitudinal-torsional vibration translation body extending from the flange that is structured and operable to helically propagate the ultrasonic vibration between the flange and a distal end of the longitudinal-torsional vibration translation body.

8. The printhead of claim 7, wherein the longitudinal-torsional vibration translation body comprises:
transducer vibration translation body termination collar; and
a plurality of helically shaped wave guide structures that extend from the flange to the transducer vibration translation body termination collar.

9. The printhead of claim 4 further comprising a mixing reservoir disposed between a distal end of the vibration translation body and the dispensing nozzle, wherein the mixing reservoir is structured and operable to receive the print material from the print material reservoir and mix the print material via vibration from the piezoelectric head and transducer assembly.

10. A piezoelectric ultrasonic vibration printing enhancement module (PEM) for use in a printhead, said module comprising:
a PEM head chassis; and
a piezoelectric head and transducer assembly, the piezoelectric head and transducer assembly comprising:
a PEM head retained within the PEM head chassis and structured and operable to generate the ultrasonic vibration; and
a transducer mechanically connected to the PEM head.

11. The module of claim 10, wherein the PEM head comprises:
a plurality of electrodes; and
a plurality of piezoelectric ceramic disks disposed between the plurality of electrodes that are structured and operable to generate the ultrasonic vibration.

12. The module of claim 11, wherein the transducer comprises:
a flange; and
a vibration translation body extending from the flange that is structured and operable to propagate the ultrasonic vibration between the flange and a distal end of the vibration translation body.

13. The module of claim 12, wherein vibration translation body comprises a longitudinal vibration translation body having a plurality of consecutive cylindrical sections wherein each consecutive cylindrical section from the flange to the distal end has an outer diameter that is smaller than the preceding.

14. The module of claim 13, wherein the longitudinal vibration translation body further comprises plurality of tapered sections, wherein each tapered is integrally formed between two consecutive cylindrical sections.

15. The module of claim 11, wherein the vibration translation body comprises a longitudinal-torsional vibration translation body extending from the flange that is structured and operable to helically propagate the ultrasonic vibration between the flange and a distal end of the longitudinal-torsional vibration translation body.

16. The module of claim 15, wherein the longitudinal-torsional vibration translation body comprises:
transducer vibration translation body termination collar; and
a plurality of helically shaped wave guide structures that extend from the flange to the transducer vibration translation body termination collar.

17. The module of claim 11 further comprising a mixing reservoir disposed between a distal end of the vibration translation body and a dispensing nozzle of a printhead in which the PEM is installed, wherein the mixing reservoir is structured and operable to receive the print material from the print material reservoir and mix the print material via vibration from the piezoelectric head and transducer assembly.

18. A piezoelectric head and transducer assembly for use in a printhead, the piezoelectric head and transducer assembly comprising:
a piezoelectric ultrasonic vibration printing enhancement module (PEM) head structured and operable to generate the ultrasonic vibration; and
a transducer mechanically connected to the PEM head,
wherein the PEM comprises:
a plurality of electrodes; and
a plurality of piezoelectric ceramic disks disposed between the plurality of electrodes that are structured and operable to generate the ultrasonic vibration.

19. The assembly of claim 18, wherein the transducer comprises:
a flange; and
a longitudinal vibration translation body extending from the flange that is structured and operable to linearly propagate the ultrasonic vibration between the flange and a distal end of the longitudinal vibration translation body,
wherein the longitudinal vibration translation body comprises a plurality of consecutive cylindrical sections wherein each consecutive cylindrical section from the flange to the distal end has an outer diameter that is smaller than the preceding.

20. The assembly of claim 18, wherein the transducer comprises:
a flange; and
a longitudinal-torsional vibration translation body extending from the flange that is structured and operable to helically propagate the ultrasonic vibration between the flange and a distal end of the longitudinal-torsional vibration translation body,
wherein the longitudinal-torsional vibration translation body comprises:
transducer vibration translation body termination collar; and
a plurality of helically shaped wave guide structures that extend from the flange to the transducer vibration translation body termination collar.
